(19) United States
(12) Patent Application Publication
(10) Pub. No.: US 2017/0130035 A1
(43) Pub. Date: May 11, 2017

(54) WAVELENGTH CONVERSION MATERIAL AND SOLAR CELL SEALING FILM CONTAINING THE SAME

(71) Applicant: BRIDGESTONE CORPORATION, Tokyo (JP)

(72) Inventors: Hisataka KATAOKA, Tokyo (JP); Keiko NISHIDA, Nomi-shi (JP)

(73) Assignee: BRIDGESTONE CORPORATION, Tokyo (JP)

(21) Appl. No.: 15/319,012

(22) PCT Filed: Jun. 17, 2015
(86) PCT No.: PCT/JP2015/067476

§ 371 Date: Dec. 15, 2016

(30) Foreign Application Priority Data
Jun. 17, 2014 (JP) 2014-124156
Jun. 17, 2014 (JP) 2014-124184

(51) Int. Cl. C08K 9/10; H01L 31/0216; C08L 31/04; C09K 11/02; C09K 11/06

(52) U.S. Cl. CPC C08K 9/10; C09K 11/025; C09K 11/06; C08L 31/04; H01L 31/02168; C09K 2211/182

(57) ABSTRACT

Provided is a wavelength conversion material composed of resin particles comprising an acrylic resin and an organic rare earth complex contained in the acrylic resin, in which the acrylic resin is obtained from an acrylic resin composition comprising a cross-linking agent, and deterioration of the organic rare earth complex is prevented. A wavelength conversion material composed of resin particles comprising an acrylic resin and an organic rare earth complex contained in the acrylic resin, wherein the acrylic resin is a polymer which is a reaction product of an acrylic resin composition comprising a (meth)acrylate monomer, a crosslinking agent and an azo polymerization initiator, wherein the crosslinking agent is a compound represented by the following formula (I):

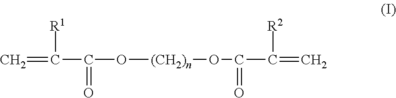

where R¹ and R² each independently represent a hydrogen atom or a methyl group and n represents an integer of 2 to 14, and the content of the cross-linking agent is: 0.1 to 5 parts by mass based on 100 parts by mass of the (meth)acrylate monomer when n in formula (I) is 2; or 0.1 to 50 parts by mass based on 100 parts by mass of the (meth)acrylate monomer when n in formula (I) is 3 to 14.

### TECHNICAL FIELD

The present invention relates to a wavelength conversion material composed of resin particles containing an organic rare earth complex, and particularly relates to a wavelength conversion material that is highly stable in high temperature and high humidity environments. The present invention also relates to a solar cell sealing film comprising the wavelength conversion material, and thereby enables to increase light having a certain wavelength contributing to power generation of solar cells to improve power generation efficiency.

### BACKGROUND ART

Wavelength conversion materials have the property of absorbing light of a certain wavelength and then emitting light of another wavelength. Wavelength conversion materials have been used in various apparatuses such as electrical apparatuses, optical apparatuses and display apparatuses, and agricultural materials. Particularly, materials for converting UV (ultraviolet) light into visible light or near-infrared light have recently attracted attention in the field of solar cell modules. More specifically, solar cells such as crystalline silicon cells that convert sunlight directly into electrical energy have low spectral sensitivity to UV light and thus do not effectively use sunlight energy. Thus, there has been proposed a technique for improving power generation efficiency of solar cells by incorporating a layer containing a wavelength conversion material onto the light-receiving side of a solar cell to emit light having a wavelength that largely contributes to power generation of the solar cell.

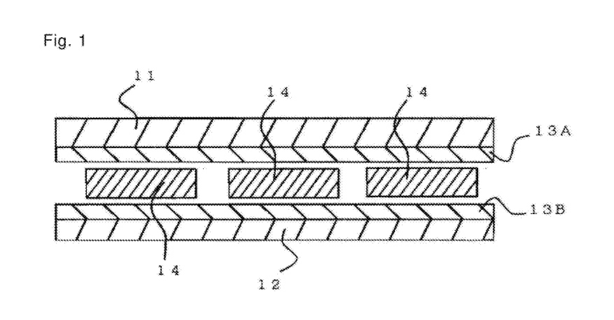

As shown in FIG. 1, a solar cell module is generally produced by stacking a front-side transparent protecting member 11 such as a glass substrate, a front-side sealing film 13A formed of a resin material such as ethylene-vinyl acetate copolymer (EVA), solar cells 14 such as crystalline silicon cells, a backside sealing film 13B and a backside protecting member (back cover) 12 in this order to give a stack, then degassing the stack under reduced pressure, applying heat and pressure to the stack to cure the front-side sealing film 13A and the backside sealing film 13B by crosslinking, thereby adhering the above members, films and solar cells.

Fluorescent materials such as organic rare earth complexes used as wavelength conversion materials have disadvantages in that fluorescent materials have low dispersibility in resin materials such as EVA and easily deteriorate. To address the disadvantages, Patent Document 1 proposes a solar cell sealing film obtained by containing a fluorescent material such as an organic rare earth complex having an absorption peak at 300 to 450 nm and a fluorescence peak at 500 to 900 nm in resin particles formed from a vinyl compound, and then dispersing the particles in the sealing film.

### PRIOR ART DOCUMENT(S)

### Patent Document(s)

Patent Document 1: JP A 2012-33605

### SUMMARY OF INVENTION

### Problems to be Solved by the Invention

The present inventors studied resin materials used for making resin particles in which an organic rare earth complex is contained. As a result, they found that when acrylic resins comprising poly(methyl methacrylate) (PMMA) as a main component are used as the resin materials, a sufficient degree of cross-linking can be ensured and swelling of the resin particle can be prevented by blending a cross-linking agent, which means a monomer having a plurality of polymerizable double bonds in the present invention, with the result that generation of bubbles, an increase of a haze value and reduction in transmittance can be suppressed. However the organic rare earth complex deteriorates and luminescence properties may decrease.

Accordingly, an object of the invention is to provide a wavelength conversion material composed of resin particles comprising an acrylic resin and an organic rare earth complex contained in the acrylic resin, in which the acrylic resin is obtained from an acrylic resin composition comprising a cross-linking agent, and deterioration of the organic rare earth complex is prevented.

Another object of the invention is to provide a solar cell sealing film comprising the wavelength conversion material, in which the effect of improving power generation efficiency is maintained for a long term.

Another object of the invention is to provide a solar cell module prepared using the solar cell sealing film, in which high power generation is maintained.

### Means for Solving the Problems

The above object can be achieved by a wavelength conversion material composed of resin particles comprising an acrylic resin and an organic rare earth complex contained in the acrylic resin, wherein the acrylic resin is a polymer which is a reaction product of an acrylic resin composition comprising a (meth)acrylate monomer, a crosslinking agent and an azo polymerization initiator, wherein

the crosslinking agent is a compound represented by the following formula (I):

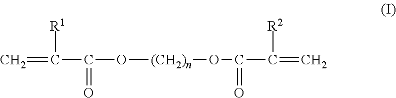

where R¹ and R² each independently represent a hydrogen atom or a methyl group and n represents an integer of 2 to 14, and

the content of the cross-linking agent is: 0.1 to 5 parts by mass based on 100 parts by mass of the (meth)acrylate monomer when n in formula (I) is 2; or 0.1 to 50 parts by mass based on 100 parts by mass of the (meth)acrylate monomer when n in formula (I) is 3 to 14.

The present inventors studied causes of deterioration of organic rare earth complexes in acrylic resins comprising cross-linking agents. As a result, they considered that in the case where cross-linking agents which are generally used, i.e., polyethylene glycol di(meth)acrylates (the number of ethylene groups: 2 or more) are used, since hydrophilicity of ethylene oxide group is high, the resultant acrylic resins easily absorb moisture, with the result that components of resin compositions are hydrolyzed to generate acids, which causes deterioration of organic rare earth complexes.

Then, in the present invention, the amount of hydrophilic components is reduced by selecting a di(meth)acrylate compound having a linear alkylene group represented by the above formula (I) as a cross-linking agent. As for the cross-linking agent represented by formula (I) where n is 2, since a single ethylene oxide group having high hydrophilicity is contained, the content is limited to 0.1 to 5 parts by mass based on 100 pats by mass of the (meth)acrylate monomer in order to suppress hygroscopicity of the resultant acrylic resin. When n is 3 to 14, since the influence of linear alkylene group having high hydrophobicity increases, the content is 0.1 to 50 parts by mass based on 100 parts by mass of the (meth)acrylate monomer. In this manner, the hygroscopicity of the acrylic resin is suppressed and acid generation is suppressed, with the result that deterioration of an organic rare earth complex contained in the acrylic resin can be prevented.

Preferred embodiments of the wavelength conversion material according to the present invention are as follows:
(1) The cross-linking agent is a compound represented by formula (I) where R¹ and R² are methyl groups and n is 2. This cross-linking agent is more effective.
(2) The cross-linking agent is a compound represented by formula (I) where R¹ and R² are methyl groups and n is 9. This cross-linking agent has proper hydrophobicity and is more effective
(3) The (meth)acrylate monomer is methyl methacrylate.
(4) The organic rare earth complex is a europium complex represented by the following formula (II):

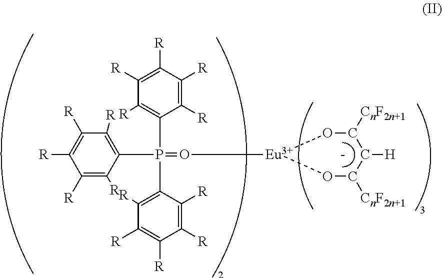

where R's each independently represent a hydrogen atom or a hydrocarbon group having 1 to 20 carbon atoms that may be optionally substituted; and n represents an integer of 1 to 4. The europium complex is excellent in UV resistance; however, deterioration may be sometimes caused with an acid. In the present invention, deterioration with an acid is prevented by enclosing the europium complex in the acrylic resin, with the result that a wavelength conversion material having higher weather resistance can be obtained.
(5) The organic rare earth complex described in (4) is a europium complex represented by formula (II) where R's all represent hydrogen atoms and n is 1.

In addition, the above object is achieved by a solar cell sealing film comprising a resin material comprising an olefin (co)polymer and the above wavelength conversion material. The solar cell sealing film comprising the wavelength conversion material of the present invention is capable of maintaining the effect of improving power generation efficiency for a long term.

Preferred embodiments of the solar cell sealing film of the present invention are as follows.

(1) The olefin (co)polymer is one or more polymers selected from the group consisting of metallocene catalyzed ethylene-α-olefin copolymers (m-LLDPE), low density polyethylenes (LDPE), linear low density polyethylenes (LLDPE), polypropylenes, polybutenes and ethylene-polar monomer copolymers.

(2) The olefin (co)polymer is a metallocene catalyzed ethylene-α-olefin copolymer (m-LLDPE) and/or an ethylene-polar monomer copolymer. Sealing films which are excellent in processability, capable of forming a crosslinked structure with a crosslinking agent and high in adhesiveness can be obtained.

(3) The ethylene-polar monomer copolymer is an ethylene-vinyl acetate copolymer or an ethylene-methyl (meth)acrylate copolymer (EMMA). Sealing films having more excellent transparency and excellent flexibility can be obtained.

Further, the aforementioned object can be achieved by a solar cell module formed by sealing a solar cell with the solar cell sealing film of the present invention. Since the solar cell module of the present invention is prepared using the solar cell sealing film of the present invention, the solar cell module of the present invention is improved in power generation efficiency of a solar cell by the wavelength conversion material, and thus is capable of maintaining high power generation efficiency for a long term.

### Effects of the Invention

The wavelength conversion material of the present invention is composed of resin particles comprising an organic rare earth complex contained in an acrylic resin. The acrylic resin is obtained from a resin composition containing a certain cross-linking agent in a certain amount. Because of this, deterioration of the organic rare earth complex in the resin is prevented. Accordingly, the wavelength conversion material of the present invention is useful because even if it is added to a solar cell sealing film or the like, the wavelength conversion effect is maintained for a long term.

The wavelength conversion material of the present invention is composed of resin particles comprising an acrylic resin containing an organic rare earth complex. The acrylic resin is a polymer which is a reaction product of an acrylic resin composition comprising a (meth)acrylate monomer, a cross-linking agent and an azo polymerization initiator. The cross-linking agent is a compound represented by the following formula (I):

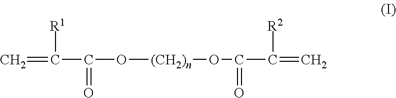

where R¹ and R² each independently represent a hydrogen atom or a methyl group and n represents an integer of 2 to 14, and the content of the cross-linking agent is 0.1 to 5 parts by mass based on 100 parts by mass of the (meth)acrylate monomer when n in formula (I) is 2, or 0.1 to 50 parts by mass based on 100 parts by mass of the (meth)acrylate monomer when n in formula (I) is 3 to 14.

The acrylic resin is generally a resin obtained by polymerizing a (meth)acrylic monomer such as methyl (meth)acrylate as a main component. It is known that a cross-linked structure is given to an acrylic resin by adding a cross-linking agent (i.e., a monomer having a plurality of polymerizable double bonds) to a polymerization reaction composition, with the result that a degree of crosslinking can be increased.

A sufficient degree of crosslinking is ensured and swelling of resin particles due to the effect of additives and a solvent concomitantly used can be prevented, and poor appearance due to void generation, generation of bubbles, an increase of a haze value and a decrease of transmittance can be suppressed. However, when polyethylene glycol di(meth)acrylates (the number of ethylene groups is 2 or more) generally used as crosslinking agents are used in the acrylic resin in which an organic rare earth complex is contained, the organic rare earth complex may deteriorate.

The cause was considered as follows: since the hydrophilicity of ethylene oxide groups is high, the resultant acrylic resin is likely to absorb moisture, with the result that components of a resin composition are hydrolyzed to generate acids, which deteriorates the organic rare earth complex. In the present invention, the amount of hydrophilic components is reduced by selecting a di(meth)acrylate compound having a linear alkylene group as shown in the above formula (I) as a cross-linking agent. Examples of the di(meth)acrylate compound include ethylene glycol di(meth)acrylate, 1,4-butanediol di(meth)acrylate, 1,6-hexanediol di(meth)acrylate, 1,9-nonanediol di(meth)acrylate and 1,14-tetradecanediol di(meth)acrylate. It should be noted that the “(meth)acrylate” represents an “acrylate or methacrylate”.

In formula (I), the case where n is 2 means that a single ethylene oxide group that has high hydrophilicity is contained. Thus, in order to suppress hygroscopicity of the resultant acrylic resin, the content thereof is limited to 0.1 to 5 parts by mass based on 100 parts by mass of the (meth)acrylate monomer. The case where n is 3 to 14 means that the influence of linear alkylene group having high hydrophobicity increases, and thus, the content thereof is 0.1 to 50 parts by mass based on 100 parts by mass of the (meth)acrylate monomer. Owing to this, hygroscopicity of the acrylic resin is suppressed and acids are not readily generated, with the result that deterioration of an organic rare earth complex in the acrylic resin can be prevented.

The wavelength conversion material of the present invention is the one that is capable of maintaining the wavelength conversion effect for a long term when it is added to a solar cell sealing film of the like. Since the solar cell sealing film of the present invention comprises the wavelength conversion material, the solar cell sealing film can maintain the effect of improving power generation efficiency for a long term.

In the present invention, the cross-linking agent described above is a compound represented by formula (I) where R¹ and R² are methyl groups and n is 2. More specifically, the cross-linking agent is preferably ethylene glycol dimethacrylate. The hygroscopicity of the resultant acrylic resin can be more suppressed and satisfactory transparency of resin particles can be obtained.

The content of the cross-linking agent is more preferably 0.5 to 5 parts by mass based on 100 parts by mass of the (meth)acrylate monomer, particularly preferably 1 to 5 parts by weight for a compound represented by formula (I) where n is 2. The cross-linking agent is also preferably a compound represented by formula (I) where R¹ and R² are methyl groups and n is 9, and more specifically, 1,9-nonanediol dimethacrylate. If the chain length (n) of the linear alkylene group becomes excessively large, the hydrophobicity becomes excessively high, with the result that the transparency of the resultant acrylic resin may decrease. The dimethacrylate has a proper hydrophobicity and is a more effective cross-linking agent. The content of the cross-linking agent is more preferably 0.5 to 50 parts by mass based on 100 parts by mass of the (meth)acrylate monomer, particularly preferably 1 to 25 parts by mass for a compound represented by formula (I) where n is 3 to 14.

In the present invention, as described above, the acrylic resin is a polymer obtained by a reaction of an acrylic resin composition comprising a (meth)acrylate monomer as a main component and an azo polymerization initiator in addition to the aforementioned cross-linking agent. Examples of the (meth)acrylate monomer include, but are not limited to, methyl (meth)acrylate, ethyl (meth)acrylate, n-butyl (meth)acrylate, isobutyl (meth)acrylate, dodecyl (meth)acrylate, stearyl (meth)acrylate, 2-ethylhexyl (meth)acrylate and tetrahydrofurfuryl (meth)acrylate. These (meth)acrylate monomers may be used alone or in combination of two or more.

Methyl (meth)acrylate is preferably used as the (meth)acrylate monomer and methyl methacrylate is particularly preferably used, so that the refractive index of the resultant acrylic resin is brought closer to that of the resin material for a solar cell sealing film. Owing to the use of the above monomers, even if resin particles are added to a solar cell sealing films or the like, a decrease in transparency derived from difference in refractive index is not readily caused, with the result that more highly transparent solar cell sealing films can be obtained.

In the present invention, the azo polymerization initiator used as a polymerization initiator initiates a reaction at a relatively low temperature and thus suitable for use in polymerization reaction in accordance with a suspension polymerization reaction described below. Examples of the azo polymerization initiator include, but are not limited to, 2,2′-azobis(isobutyronitrile) (AIBN), 2,2′-azobis(2,4-dimethylvaleronitrile), 2,2′-azobis(2-methylbutyronitrile), 2,2′-azobis(4-methoxy-2,4-dimethylvaleronitrile) and dimethyl-2,2′-azobisisobutyrate. The content of the azo polymerization initiator in an acrylic resin composition is, but not limited to, preferably 0.01 to 5 parts by mass, preferably 0.01 to 1 part by mass, particularly preferably 0.05 to 0.5 parts by mass, based on 100 parts by mass of the (meth)acrylate monomer.

In the present invention, an organic peroxide may be contained as a polymerization initiator in addition to an azo polymerization initiator. Examples of the polymerization initiator include benzoyl peroxide, 4-methylbenzoyl peroxide, isobutyryl peroxide, 1,1-di(t-butylperoxy)-2-methylcyclohexane, bis(4-t-butylcyclohexyl) peroxydicarbonate, pivaloyl t-butylperoxide, pivaloyl t-hexylperoxide, dilauroyl peroxide, 1,1,3,3-tetramethylbutylperoxy-2-ethylhexanoate, t-hexylperoxy-2-hexanoate and t-butylperoxy-2-ethylhexanoate. The content of the organic peroxide in the acrylic resin composition is, but not limited to, preferably 0.01 to 2 parts by mass, preferably 0.05 to 1 part by mass, particularly preferably 0.1 to 0.5 parts by mass based on 100 parts by mass of the (meth)acrylate monomer.

In the present invention, the acrylic resin composition may further contain other monomer(s) copolymerizable with a (meth)acrylate monomer, particularly a methyl methacrylate as long as the objects of the invention are not damaged. Examples thereof include styrenic monomers such as styrene, fluorine-containing monomers such as trifluoromethyl (meth)acrylate, acrylonitrile, vinyl acetate, (meth)acrylic acid, glycidyl methacrylate and hydroxyethyl methacrylate. The content of the other monomer(s) is, but not limited to, preferably 1 to 40 parts by mass, preferably 5 to 30 parts by mass, particularly preferably 10 to 20 parts by mass based on 100 parts by mass of the (meth)acrylate monomer.

In the present invention, a method for polymerizing the above monomer to obtain an acrylic resin is not limited. Any method known in the art such as suspension polymerization and emulsion polymerization can be employed. Suspension polymerization is preferred for the reason that the reaction can be easily controlled. In the suspension polymerization, the monomer(s) as mentioned is polymerized in a solvent such as water in the presence of a polymerization initiator mentioned above.

The solvent may contain an organic solvent in addition to water. Examples of the organic solvent include alcohols such as methanol, ethanol, isopropanol, n-butanol, isobutanol, sec-butanol, t-butanol, pentanol, ethylene glycol, propylene glycol and 1,4-butanediol; ketones such as acetone and methyl ethyl ketone; esters such as ethyl acetate; (cyclo) paraffins such as isooctane and cyclohexane; and aromatic hydrocarbons such as benzene and toluene. These may be used alone or in combination of two or more. The temperature of the polymerization reaction can be appropriately controlled in accordance with the polymerization initiator used. When two types or more polymerization initiators are used, polymerization can be carried out by changing temperature stepwise.

In the present invention, examples of a method for containing an organic rare earth complex in an acrylic resin include a method of dissolving or dispersing an organic rare earth complex in the acrylic resin composition and subjecting the composition to suspension polymerization to enclose the organic rare earth complex into a resin particle.

In the present invention, the shape of the resin particle is not limited; however, a spherical shape is preferable for the reason that dispersibility and light scattering are low. The average particle diameter of the resin particles is not limited. However, if the average particle diameter is excessively large, the surface area per weight of the particles decreases, with the result that the light-emitting efficiency may decrease. Meanwhile, if the average particle diameter is excessively small, resin particles are easily scattered, not easily handled, likely to bind to each other and sometimes reduced in dispersibility. Accordingly, the average particle diameter of the resin particles is preferably 0.1 to 300 μm, more preferably 1 to 200 μm, particularly preferably 10 to 150 μm. The average particle diameter of the resin particles can be obtained by a laser diffraction method or based on images obtained by an optical microscope or an electron microscope.

[Organic Rare Earth Complex]

In the present invention, any organic rare earth complex may be used. Examples of organic rare earth complexes include lanthanoid complexes such as europium, cerium and terbium complexes. In particular, europium complexes are preferred for the reason that europium complexes have high fluorescent intensity; stokes shift (difference between the maximum excitation-wavelength and maximum emission-wavelength) is large; and the lifetime of fluorescence is long. Europium complexes are composed of Eu ion (Eu³⁺) and an organic ligand. Examples of europium complexes include Eu(hfa)₃(TPPO)₂, Eu(hfa)₃(BIPHEPO) and Eu(TTA)₃Phen. Particularly, in terms of weather resistance, it is preferable to use a europium complex represented by the following formula (II):

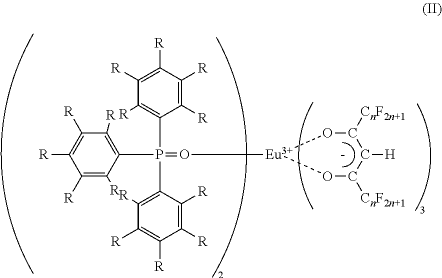

where R's each independently represent a hydrogen atom or a hydrocarbon group having 1 to 20 carbon atoms that may be optionally substituted; and n represents an integer of 1 to 4, preferably 1. The hydrocarbon group having 1 to 20 carbon atoms may be aliphatic or aromatic; may have an unsaturated bond and a hetero atom; and may be linear or branched. Examples of the hydrocarbon group include alkyl groups (e.g., methyl group, ethyl group, propyl groups), alkenyl groups (e.g., vinyl group, allyl group, butenyl groups), alkynyl groups (e.g., ethynyl group, propynyl group, butynyl groups), cycloalkyl group, cycloalkenyl groups, phenyl groups, naphthyl groups and biphenyl groups. The above hydrocarbon groups may optionally have one or more substituents. Examples of the substituents include halogen atoms, hydroxyl group, amino group, nitro group and sulfo group. All R's in formula (I) are preferably hydrogen atoms.

The europium complex represented by formula (II) is preferred as the organic rare metal complex added to solar cell sealing films or the like, since it has excellent UV resistance; however, the complex may be deteriorated with acids. In the present invention, the europium complex is contained in an acrylic resin as mentioned above, with the result that deterioration with acids is prevented. Owing to this, the europium complex can be used as a wavelength conversion material having higher weather resistance.

The above europium complex is preferably Eu(hfa)₃(TPPO)₂ represented by formula (II) where n is 1 and all R's are hydrogen atoms, because the complex has more excellent UV resistance. Eu(hfa)₃(TPPO)₂ is a europium complex in which two ligands, i.e. triphenylphosphine oxide and hexafluoro acetylacetone, are coordinated to a center element of europium (a rare-earth metal).

The content of the organic rare earth complex in a resin particle is not limited and can be appropriately adjusted depending on the use of the wavelength conversion material. The greater the content of the organic rare earth complex in resin particles, the more advantageous, because the emission intensity increases. However, if the content is excessively large, transparency may be sometimes affected. More specifically, if an excessively large amount of the organic rare earth complex is added to a solar cell sealing film, the power generation efficiency of the solar cell module may decrease in some cases. This is also unfavorable in terms of cost. Accordingly, the content of the organic rare earth complex in resin particles is preferably 0.01 to 10% by weight, more preferably 0.05 to 5% by mass, particularly preferably 0.1 to 1% by mass.

Uses of the wavelength conversion material of the present invention are not limited. The wavelength conversion material can be used, for example, in solar cell sealing films, agricultural film materials, optical apparatuses and display apparatuses. The wavelength conversion material of the present invention is preferably applied to outside uses, and particularly preferably added to solar cell sealing films. This is because deterioration of organic rare earth complexes is suppressed and weather resistance is high. The solar cell sealing film is a sealing film used in, for example, a solar cell module shown in FIG. 1.

As described above, the solar cell sealing film of the present invention comprises a resin material comprising an olefin (co)polymer and the wavelength conversion material of the present invention. The solar cell sealing film of the present invention will be described below.

[Resin Material]

In the present invention, the resin material of the solar cell sealing film comprises an olefin (co)polymer as a main component. The olefin (co)polymer herein refers to an olefin polymer or copolymer. Examples of the olefin polymer or copolymer include ethylene-α-olefin (co)polymers, for example, metallocene catalyzed ethylene-α-olefin copolymers (m-LLDPE), polyethylenes, for example, low-density polyethylenes (LDPE) and linear low density polyethylenes (LLDPE), polypropylenes, polybutenes, and copolymers of an olefin and a polar monomer such as ethylene-polar monomer copolymers. The olefin (co)polymers have adhesiveness, transparency and other properties required for solar cell sealing films. The above-mentioned polymers and copolymers may be used singly or as a mixture of two or more.

In the present invention, the olefin (co)polymer is preferably at least one polymer selected from the group consisting of metallocene catalyzed ethylene-α-olefin copolymers (m-LLDPE), low density polyethylenes (LDPE), linear low density polyethylenes (LLDPE), polypropylenes, polybutenes and ethylene-polar monomer copolymers. Particularly, the olefin (co)polymer is preferably an metallocene catalyzed ethylene-e-olefin copolymer (m-LLDPE) and/or an ethylene-polar monomer copolymer, because these copolymers are excellent in processability, capable of forming a crosslinked structure by a crosslinking agent and successfully providing solar cell sealing films having high adhesiveness.

(Metallocene Catalyzed Ethylene-α-Olefin Copolymer (m-LLDPE))

This copolymer, m-LLDPE, is an ethylene-α-olefin copolymer, (also including terpolymer, etc.), which comprises a structural unit derived from ethylene as a main component and further comprises single or a plurality of types of structural units derived from α-olefin(s) having 3 to 12 carbon atoms, such as propylene, 1-butene, 1-hexene, 1-octene, 4-methylpentene-1,4-methyl-hexene-1 and 4,4-dimethyl-pentene-1. Specific examples of the ethylene-α-olefin copolymer include ethylene-1-butene copolymers, ethylene-1-octene copolymers, ethylene-4-methyl-pentene-1 copolymers, ethylene-butene-hexene terpolymers, ethylene-propylene-octene terpolymers and ethylene-butene-octene terpolymers.

The content of α-olefin in the ethylene-α-olefin (co)polymer is preferably 5 to 40% by mass, more preferably 10 to 35% by mass, further preferably 15 to 30% by mass. If the content of α-olefin is too small, flexibility and impact resistance of the resultant solar cell sealing film may insufficient. If the content is excessive, the heat resistance may be reduced.

The metallocene catalyst for producing m-LLPDE is not limited and any metallocene catalyst known in the art may be used. A metallocene catalyst is generally a combination of a metallocene compound, which is a compound having a structure in which a transition metal such as titanium, zirconium and hafnium is sandwiched by unsaturated cyclic compounds containing e.g., a π electronic system cyclopentadienyl group or a substituted cyclopentadienyl group, and an aluminum compound (serving as a co-catalyst) such as an alkyl aluminoxane, an alkyl aluminum, an aluminum halide and an alkyl aluminum halide. The metallocene catalyst has active spots uniformly present (single site catalyst). Due to the feature, usually, polymers having a narrow molecular weight distribution and virtually the same content of co-monomer per molecule can be obtained.

In the present invention, the density (according to JIS K 7112, the same will apply to the following) of m-LLDPE is, but not limited to, preferably 0.860 to 0.930 g/cm³. The melt flow rate (MFR) (according to JIS-K7210) of m-LLDPE is, but not limited to, preferably 1.0 g/10 min or more, more preferably 1.0 to 50.0 g/10 min, further preferably 3.0 to 30.0 g/10 min. The MFR is determined at a temperature of 190° C. and a load of 21.18 N.

In the present invention, any commercially available m-LLDPE can be used. Examples thereof include Harmolex series and KERNEL series manufactured by Japan Polyethylene Corporation, Evolue series manufactured by Prime Polymer Co., Ltd., Excellen GMH series and Excellen FX series manufactured by Sumitomo Chemical Co., Ltd.

(Ethylene-Polar Monomer Copolymer)

Examples of the polar monomer of the ethylene-polar monomer copolymer include vinyl esters, unsaturated carboxylic acids and salts, esters and amides thereof, and carbon monoxide. Specific examples thereof include one or more of vinyl esters such as vinyl acetate and vinyl propionate; unsaturated carboxylic acids such as acrylic acid, methacrylic acid, fumaric acid, itaconic acid, monomethyl maleate, monoethyl maleate, maleic anhydride and anhydrous itaconic acid; salts of the unsaturated carboxylic acids and monovalent metals such as lithium, sodium and potassium; salts of the unsaturated carboxylic acids and polyvalent metals such as magnesium, calcium and zinc; esters of unsaturated carboxylic acids such as methyl acrylate, ethyl acrylate, isopropyl acrylate, isobutyl acrylate, n-butyl acrylate, isooctyl acrylate, methyl methacrylate, ethyl methacrylate, isobutyl methacrylate and dimethyl maleate; carbon monoxide and sulfur dioxide.

Specific examples of the ethylene-polar monomer copolymer include ethylene-vinyl ester copolymers such as ethylene-vinyl acetate copolymer; ethylene-unsaturated carboxylic acid copolymers such as ethylene-acrylic acid copolymer and ethylene-methacrylic acid copolymer; ionomers in which part or all of the carboxyl groups of the ethylene-unsaturated carboxylic acid copolymers are neutralized with the aforementioned metals; ethylene-unsaturated carboxylic acid ester copolymers such as ethylene-methyl acrylate copolymer, ethylene-ethyl acrylate copolymer, ethylene-methyl methacrylate copolymer (EMMA), ethylene-isobutyl acrylate copolymer and ethylene-n-butyl acrylate copolymer; ethylene-unsaturated carboxylic acid ester-unsaturated carboxylic acid copolymers such as ethylene-isobutyl acrylate-methacrylic acid copolymer and ethylene-n-butyl acrylate-methacrylic acid copolymer; and ionomers in which part or all of the carboxyl groups of the ethylene-unsaturated carboxylic acid ester-unsaturated carboxylic acid copolymers are neutralized with the aforementioned metal.

As the ethylene-polar monomer copolymer, an ethylene-polar monomer copolymer having a melt flow rate (defined by JIS K7210) of 35 g/10 min or less, particularly 3 to 6 g/10 min, is preferably used. If an ethylene-polar monomer copolymer having such a melt flow rate is used, solar cell sealing films having excellent processability are provided. In the present invention, values of the melt flow rate (MFR) are determined in accordance with JIS K7210 at a temperature of 190° C. and a load of 21.18 N.

As the ethylene-polar monomer copolymer, ethylene-vinyl acetate copolymer (EVA), ethylene-methyl methacrylate copolymer (EMMA), ethylene-ethyl methacrylate copolymer, ethylene-methyl acrylate copolymer and ethylene-ethyl acrylate copolymer are preferred, and EVA and EMMA are particularly preferred. If these copolymers are used, solar cell sealing films that are inexpensive and excellent in transparency and flexibility are provided. If such solar cell sealing films are used, solar cell modules that are more excellent in durability and having high power generation efficiency are provided.

The content of vinyl acetate in EVA is preferably 20 to 35% by mass, further preferably 22 to 30% by mass and particularly preferably 24 to 28% by mass, based on the EVA. The lower the content of a vinyl acetate unit in EVA is, the harder the resultant sheet tends to be. If the content of vinyl acetate is excessively low, the transparency of the sheet obtained through crosslinking/curing at high temperature may be insufficient. Meanwhile, if the content of vinyl acetate is excessively high, the hardness of the resultant sheet may be insufficient.

The content of methyl methacrylate in EMMA is preferably 20 to 30% by mass, further preferably 22 to 28% by mass. If the content falls within the range, sealing films having high transparency can be obtained and solar cell modules having high power generation efficiency can be obtained.

The density of the olefin (co)polymer is, but not limited to, generally 0.80 to 1.0 g/cm³, preferably 0.85 to 0.95 g/cm³.

In the present invention, at least one resin such as polyvinylacetal resins (for example, polyvinyl formal, polyvinyl butyral (PVB resin), modified PVB) may be secondarily added to the resin material, in addition to the aforementioned olefin (co)polymer.

[Organic Peroxide and Photopolymerization Initiator]

In the solar cell sealing film of the present invention, organic peroxide(s) or photopolymerization initiator(s) is preferably added to form a cross-linked structure of an ethylene-polar monomer copolymer. An organic peroxide is preferably used since sealing films improved in adhesion force, humidity resistance and temperature dependency of penetrability resistance are provided.

As the organic peroxide, any organic peroxide can be used as long as it is decomposed at a temperature of 100° C. or more to generate radicals. The organic peroxide used is generally selected in consideration of film forming temperatures, conditions for preparing compositions, curing temperatures, heat resistance of an object to be attached and storage stability. Particularly, organic peroxides having a half-life period of 10 hours and a decomposition temperature of 70° C. or more are preferred.

Examples of organic peroxides include 2,5-dimethyl-2,5-bis(t-butylperoxy)hexane, 2,5-dimethylhexane-2,5-dihydroperoxide, 3-di-t-butylperoxide, dicumylperoxide, 2,5-dimethyl-2,5-bis(t-butylperoxy)hexyne, α,α′-bis(t-butylperoxyisopropyl)benzene, n-butyl-4,4-bis(t-butylperoxy)butane, t-butylperoxyl-2-ethylhexylmonocarbonate, t-hexylperoxyisopropyl monocarbonate, 2,2-bis(t-butylperoxy)butane, 1,1-bis(t-hexylperoxy)-3,3,5-trimethylcyclohexane, 1,1-bis(t-butylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecan, 1,1-bis(t-butylperoxy)cyclohexane and benzoylperoxide curing agent (e.g., t-butyl peroxybenzoate).

Of the above organic peroxides, 2,5-dimethyl-2,5-di(tert-butylperoxy)hexane and/or t-butylperoxy-2-ethylhexylmonocarbonate is preferred. The use of these organic peroxides enables to provide solar cell sealing films that are satisfactorily crosslinked and have excellent transparency.

The content of an organic peroxide to be used in solar cell sealing film is preferably 0.1 to 5 parts by weight, more preferably 0.2 to 3 parts by weight based on 100 parts by mass of the resin material. If the content of organic peroxide is too low, the crosslinking rate during a crosslinking/curing process may decrease. If the content is too large, compatibility with a copolymer may deteriorate.

As the photopolymerization initiator, any known photopolymerization initiator can be used. Preferred photopolymerization initiators are those exhibiting satisfactory storage stability after blending. Examples of such photopolymerization initiators include acetophenones such as 2-hydroxy-2-methyl-1-phenylpropan-1-one, 1-hydroxycyclohexylphenylketone and 2-methyl-1-(4-(methylthio)phenyl)-2-morpholinopropane-1; benzoins such as benzyldimethylketal; benzophenones such as benzophenone, 4-phenylbenzophenone and hydroxybenzophenone; and thioxanthones such as isopropylthioxanthone and 2-4-diethyl thioxanthone. Other than these, methylphenylglyoxylate can be mentioned as a specific example. Particularly preferably, e.g., 2-hydroxy-2-methyl-1-phenylpropan-1-one, 1-hydroxycyclohexylphenyl ketone, 2-methyl-1-(4-(methylthio)phenyl)-2-morpholinopropane-1 and benzophenone. These photopolymerization initiators can be used, if necessary, as a mixture with one or more photopolymerization accelerators known in the art, for example, benzoates such as 4-dimethyl amino benzoate or tertiary amines. The photopolymrization accelerators may be contained in an arbitrary ratio in the mixture. Alternatively, photopolymerization initiators may be used singly or as a mixture of two or more.

The content of the photopolymerization initiator is 0.1 to 5 parts by mass, preferably 0.2 to 3 parts by mass based on 100 parts by mass of the resin material.

[Crosslinking Aid]

The solar cell sealing film of the present invention may contain, if necessary, one or more crosslinking aids. The crosslinking aids are capable of improving a gel fraction of ethylene-polar monomer copolymers and improving the adhesiveness and durability of the sealing films.

The content of the crosslinking aid is generally 10 parts by mass or less, preferably 0.1 to 5 parts by mass, further preferably 0.1 to 2.5 parts by mass, based on 100 parts by mass of the resin material. The use of the crosslinking aid in the above amount enables to provide solar cell sealing films that are further excellent in adhesiveness.

Examples of crosslinking aids (generally, compounds having a radical polymerizable group as a functional group) may include, trifunctional crosslinking aids such as triallyl cyanurate and triallyl isocyanurate, monofunctional or difunctional crosslinking aids such as (meth)acryl esters (e.g., NK ester). Triallyl cyanurate and triallyl isocyanurate are preferred, and triallyl isocyanurate is particularly preferred.

[Adhesion Improver]

The solar cell sealing film of the present invention may further contain an adhesion improver. As the adhesion improver, a silane coupling agent can be used. This enables solar cell sealing films to have further excellent adhesive strength.

Examples of the silane coupling agent include γ-chloropropyltrimethoxysilane, vinyltriethoxysilane, vinyltris(β-methoxyethoxy)silane, γ-methacryloxypropyltrimethoxysilane, vinyltriacetoxysilane, γ-glycidoxypropyltrimethoxysilane, γ-glycidoxypropyltriethoxysilane, β-(3,4-epoxycyclohexyl)ethyltrimethoxysilane, vinyltrichlorosilane, γ-mercaptopropyltrimethoxysilane, γ-aminopropyltriethoxysilane and N-β-(aminoethyl)-γ-aminopropyltrimethoxysilane. These silane coupling agents may be used singly or in combination of two or more. γ-methacryloxypropyltrimethoxysilane is particularly preferred.

The content of the silane coupling agent is preferably 0.1 to 0.7 parts by mass, particularly preferably 0.3 to 0.65 parts by mass based on 100 parts by mass of the resin material.

[Other Components]

The solar cell sealing film of the present invention may further contain, if necessary, various types of additives such as plasticizers, acryloxy group-containing compounds, methacryloxy group-containing compounds and/or epoxy group-containing compounds, in order to provide improved or controlled various physical properties (e.g., mechanical strength, optical characteristics such as transparency, heat resistance, light resistance) of the sealing film.

[Solar Cell Sealing Film]

The aforementioned solar cell sealing film of the present invention may be formed in accordance with any known method. For example, the solar cell sealing film can be manufactured by preparing resin particles containing an organic rare earth complex serving as a wavelength conversion material, as mentioned above, then mixing the resin particles with the aforementioned other materials in accordance with any known method using e.g., a super mixer (high-speed flow mixer) or a roll mill to give a composition, and finally molding the composition into a sheet-like material in accordance with any method, e.g., extrusion molding or calendering. Alternatively, sealing films can be obtained by dissolving the composition in a solvent (dispersing in the case of fine particles) and applying the dispersion solution onto an appropriate substrate by an appropriate coater, followed by drying to form a coating film. When an organic peroxide is contained in the composition, the heating temperature during the film formation process preferably falls within a temperature range in which the reaction by the organic peroxide does not proceed or hardly proceeds. The heating temperature is, for example, 50 to 90° C., particularly preferably 40 to 80° C. The thickness of the solar cell sealing film is not limited and appropriately determined depending upon the use. The thickness of the solar cell sealing film is generally 50 μm to 2 mm.

In the solar cell sealing film, the content of the wavelength conversion material (resin particles) is not limited as long as the effect of improving the power generation efficiency of solar cells can be obtained and can be controlled depending upon the content of an organic rare earth complex in resin particles. The content of the organic rare earth complex in the resin particles is preferably 0.000001 to 1 part by mass based on 100 parts by mass of the resin material of the solar cell sealing film of the present invention. If the content is lower than 0.000001 parts by mass, a sufficient effect of improving power generation efficiency may not be obtained. The content is further preferably 0.00001 parts by mass or more, particularly preferably 0.0001 parts by mass or more. Meanwhile, if the content exceeds 1 part by weight, requisite transparency for sufficiently introducing sunlight into solar cells may not be ensured. In addition, this case is likely to be unfavorable in terms of cost. The content is further preferably 0.1 parts by mass or less, particularly preferably 0.01 parts by mass or less.

[Solar Cell Module]

The structure of the solar cell module of the present invention is not limited as long as the solar cell module has a structure in which solar cell(s) is sealed with the solar cell sealing film(s) of the present invention. For example, a structure in which solar cell(s) is sealed by interposing the solar cell sealing films of the present invention between a front-side transparent protecting member and a backside protecting member, and then integrating the members, the films and the solar cells by crosslinking the films, may be mentioned. In the present invention, it should be noted that the side of the solar cell to be irradiated with light (light-receiving surface side) is referred to as the “front side”; whereas the backside of the solar cell opposite to the light-receiving surface is referred to as the “backside”.

Since the solar cell sealing film of the present invention is used in the solar cell module of the present invention, the solar cells are improved in power generation efficiency by the wavelength conversion material and the high power generation efficiency thereof is maintained for a long term.

In the solar cell module, solar cells are sufficiently sealed, for example, by stacking a front-side transparent protecting member 11, a front-side sealing film 13A, solar cells 14, a backside sealing film 13B and a backside protecting member 12 to obtain a stack and then curing the sealing films in accordance with a customary method such as applying heat and pressure to form crosslinkage.

In the process of applying heat and pressure, the stack may be heated in a vacuum laminator at a temperature of 135 to 180° C., further preferably 140 to 180° C., particularly preferably 155 to 180° C., while degassing the laminator for 0.1 to 5 minutes and then applying pressure to the stack at a pressure of 0.1 to 1.5 kg/cm² for 5 to 15 minutes. In the process of applying heat and pressure, the olefin (co)polymers contained in the front-side sealing film 13A and the backside sealing film 13B are crosslinked. In this manner, the front-side transparent protecting member 11, backside protecting member 12 and solar cells 14 are adhered together via the front-side sealing film 13A and backside sealing film 13B to seal the solar cells 14.

The power generation efficiency of the solar cell modules can be improved by the use of the solar cell sealing film of the present invention owing to the presence of a wavelength conversion material therein, as mentioned above. Thus, the solar cell sealing film is preferably used as the sealing film to be arranged on the light-receiving side of solar cells, more specifically as the sealing film 13A to be arranged between the front-side transparent protecting member 12 and the solar cells 14 in FIG. 1.

The solar cell sealing film of the present invention can be used not only in solar cell modules that have solar cells formed of single crystal or polycrystalline silicon as shown in FIG. 1 but also in thin film solar cell modules such as thin film silicon solar cell modules, thin film amorphous silicon solar cell modules and copper indium serene (CIS) solar cell modules.

Examples of the structures of such thin-film solar cell modules include a structure that the solar cell sealing film of the invention and a backside protecting member are stacked on a thin-film solar cell which is formed by chemical phase deposition method on a front-side transparent protecting member such as a glass plate, a polyimide substrate or a fluoro resin transparent substrate, and the resultant stack is laminated; a structure that the solar cell sealing film of the present invention and a front-side transparent protecting member are stacked on a thin-film solar cell which is formed on a backside protecting member, and the resultant stack is laminated; and a structure that a front-side transparent protecting member, the front side sealing film of the present invention, a thin-film solar cell element, the backside sealing film of the present invention and a backside protecting member are stacked this order and then the resultant stack is laminated. In the present invention, such photovoltaic elements and thin-film solar cell elements are collectively referred to as photovoltaic elements.

The front-side transparent protecting member 11 may be generally a glass substrate such as silicate glass substrates. The thickness of the glass substrate is generally 0.1 to 10 mm, preferably 0.3 to 5 mm. Generally, the glass substrate may be chemically or thermally reinforced.

As the backside protecting member 12, a plastic film such as polyethylene terephthalate (PET) films and polyamide films is preferably used. Furthermore, a fluorinated polyethylene film, particularly a film obtained by laminating a fluorinated polyethylene film, an Al film and a fluorinated polyethylene film in this order may be employed in consideration of heat resistance and moist/heat resistance.

The solar cell sealing film of the present invention is characteristically used at the front-side and/or the backside of solar cell modules (including thin film solar cell modules). Thus, members except the sealing film, such as a front-side transparent protecting member, a backside protecting member and solar cells, are not limited as long as they have the same structure as those known in the art.

### EXAMPLES

The present invention will be more specifically described by way of the following Examples.

[Evaluation of Wavelength Conversion Materials]
(1) Preparation of wavelength conversion materials (resin particles containing an organic rare earth complex)

Suspension polymerization using the materials shown in Table 1 was carried out by a customary method to obtain spherical resin particles (average particle size: 100 μm).
(2) Hygrothermal Deterioration Test

The wavelength conversion materials obtained as above were each placed in an ampoule bottle. Fluorescence intensity was measured by spectrophotometer (F-7000, manufactured by Hitachi High-Technologies Corporation) with the bottle opened. Measurement conditions are: photomultiplier voltage: 400 V, excitation-side slit: 20 nm, fluorescence-side slit: 10 nm and scan speed: 240 nm/min. Irradiation wavelength was set at 325 nm. The wavelength was plotted on the X axis and the amount of luminescence on the Y axis. The area of the region surrounded by the curve of the resultant function f(x) from the initiation wavelength of a luminescence peak to the termination wavelength thereof and the linear line connecting two points (X=X0 and X1) on the function f (x) was calculated and defined as a fluorescence intensity. Then, the bottles were allowed to stand still in the environment at 85° C. and 85% RH for 250 hours and the fluorescence intensity was again measured to computationally obtain the residual ratio of fluorescence intensity (from the initial state).

[Evaluation of Solar Cell Sealing Films]
(1) Preparation of Solar Cell Sealing Films

Materials were supplied to a roll mill in accordance with the formulation shown in Table 2 and kneaded at 70° C. to prepare a solar cell sealing film composition. The solar cell sealing film composition was subjected to calendering at 70° C. and allowed to cool to prepare a solar cell sealing film (thickness: 0.46 mm). In Table 2, wavelength conversion materials A to M represent the wavelength conversion materials manufactured in Examples A to H and Comparative Examples I to M shown in Table 1.
(2) Preparation of Cured Samples by Crosslinking

The solar cell sealing film obtained as above was sandwiched by two transparent glass plates (thickness 3.2 mm). The obtained stack was degassed for 2 minutes and pressurized for 8 minutes by a vacuum laminator at 90° C. to be laminated to give a laminate. Then the laminate was heated in an oven at 155° C. for 30 minutes to cure by crosslinking to prepare a sample.
(3) Evaluation Methods
(i) Light Transmittance (%)

The above sample was subjected to spectral measurement at 400 to 1000 nm by a spectrophotometer (U-4100, manufactured by Hitachi, Ltd.). The average value thereof was determined as a light transmittance (%).
(ii) Hygrothermal Deterioration Test

The above sample was measured by a spectrophotometer (F-7000, manufactured by Hitachi High-Technologies Corporation) to obtain a fluorescence intensity. Measurement conditions are: photomultiplier voltage: 400 V, excitation-side slit: 20 nm, fluorescence-side slit: 10 nm and scan speed: 240 nm/min. Irradiation wavelength was set at 325 nm. The wavelength was plotted on the X axis and the amount of luminescence on the Y axis. The area of the region surrounded by the curve of the resultant function f(x) from the initiation wavelength of a luminescence peak to the termination wavelength thereof and the linear line connecting two points X=X0 and X1 on the function f(x) was calculated and defined as a fluorescence intensity. Then, the bottles were allowed to stand still in the environment at 85° C. and 85% RH for 250 hours and the fluorescence intensity was again measured to computationally obtain the residual ratio of fluorescence intensity (from the initial state).
(4) Evaluation Results

The evaluation results are shown in Tables.

TABLE 1

| | | | Exam- | Exam- | Exam- | Exam- | Exam- | Exam- | Exam- |
|---|---|---|---|---|---|---|---|---|---|
| Resin particle | | | ple A | ple B | ple C | ple D | ple E | ple F | ple G |
| Formulation | Monomer | Methyl methacrylate | 100 | 100 | 100 | 100 | 100 | 100 | 100 |
| (parts by weight), | Polymerization | Azo polymerization initiator*¹ | 0.25 | 0.25 | 0.25 | 0.25 | 0.25 | 0.25 | 0.25 |
| (organic rare | initiator | Organic peroxide (1)*² | 0.125 | 0.125 | 0.125 | 0.125 | 0.125 | 0.125 | 0.125 |
| earth complex | Crosslinking | Crosslinking agent (1)*³ | 1 | 2.5 | 5 | — | — | — | — |
| is indicated by | agent | Crosslinking agent (2)*⁴ | — | — | — | 1 | 5 | 10 | 25 |
| weight %) | | Crosslinking agent (3)*⁵ | — | — | — | — | — | — | — |

| | | | | | | | |
|---|---|---|---|---|---|---|---|
| Organic rare earth complex*⁶ | 0.1 | 0.1 | 0.1 | 0.1 | 0.1 | 0.1 | 0.1 |

| | | | | | | | |
|---|---|---|---|---|---|---|---|
| Hygrothermal deterioration-test evaluation result, | 42 | 32 | 30 | 30 | 40 | 50 | 47 |
| residual ratio (%) | | | | | | | |

| | | | | Compar- | Compar- | Compar- | Compar- | Compar- |
|---|---|---|---|---|---|---|---|---|
| | | | | ative | ative | ative | ative | ative |
| | | | Exam- | Exam- | Exam- | Exam- | Exam- | Exam- |
| Resin particle | | | ple H | ple I | ple J | ple K | ple L | ple M |
| Formulation | Monomer | Methyl methacrylate | 100 | 100 | 100 | 100 | 100 | 100 |
| (parts by weight), | Polymerization | Azo polymerization initiator*¹ | 0.25 | 0.25 | 0.25 | 0.25 | 0.25 | 0.25 |
| (organic rare | initiator | Organic peroxide (1)*² | 0.125 | 0.125 | 0.125 | 0.125 | 0.125 | 0.125 |
| earth complex | Crosslinking | Crosslinking agent (1)*³ | — | 8 | 10 | 45 | — | — |
| is indicated by | agent | Crosslinking agent (2)*⁴ | 45 | — | — | — | 100 | — |
| weight %) | | Crosslinking agent (3)*⁵ | — | — | — | — | — | 10 |

| | | | | | | |
|---|---|---|---|---|---|---|
| Organic rare earth complex*⁶ | 0.1 | 0.1 | 0.1 | 0.1 | 0.1 | 0.1 |

| | | | | | | |
|---|---|---|---|---|---|---|
| Hygrothermal deterioration-test evaluation result, | 55 | 18 | 5 | 3 | 25 | 15 |
| residual ratio (%) | | | | | | |

Note:
*¹2,2′-Azobis(isobutyronitrile) (AIBN)
*²Benzoyl peroxide (Nyper BW (manufactured by NOF CORPORATION))
*³Ethylene glycol dimethacrylate (Light Ester EG (manufactured by KYOEISHA CHEMICAL Co., Ltd.))
*⁴1,9-Nonane diol dimethacrylate (Light Ester 1,9ND (manufactured by KYOEISHA CHEMICAL Co., Ltd.))
*⁵Nonane ethylene glycol dimethacrylate (Light Ester 9EG (manufactured by KYOEISHA CHEMICAL Co., Ltd.))
*⁶Eu(hfa)₃(TPPO)₂ (Lumisis E-300 (manufactured by Central Techno Co.,)

TABLE 2

| | | Example 1 | Example 2 | Example 3 | Example 4 | Example 5 | Example 6 | Example 7 |
|---|---|---|---|---|---|---|---|---|
| Formulation | Olefin (co)polymer (1)*⁷ | 100 | 100 | 100 | 100 | 100 | 100 | 100 |
| (parts by | Organic peroxide*⁸ | 0.35 | 0.35 | 0.35 | 0.35 | 0.35 | 0.35 | 0.35 |
| weight) | Crosslinking agent*⁹ | 0.5 | 0.5 | 0.5 | 0.5 | 0.5 | 0.5 | 0.5 |
| | Silane coupling agent*¹⁰ | 0.3 | 0.3 | 0.3 | 0.3 | 0.3 | 0.3 | 0.3 |
| | Wavelength conversion material | A | B | C | D | E | F | G |
| | (resin particle) | | | | | | | |
| | Resin-particle content | 0.3 | 0.3 | 0.3 | 0.3 | 0.3 | 0.3 | 0.3 |
| | (as organic rare earth complex) | 0.0003 | 0.0003 | 0.0003 | 0.0003 | 0.0003 | 0.0003 | 0.0003 |
| Evaluation | Light beam transmittance (%) | 91.0 | 90.9 | 91.0 | 90.8 | 90.8 | 90.9 | 91.0 |
| results | Hygrothermal deterioration-test | 48.0 | 40.6 | 35.2 | 38.9 | 46.3 | 54.6 | 60.3 |
| | evaluation result (residual ratio (%)) | | | | | | | |

| | | | Comparative | Comparative | Comparative | Comparative | Comparative |
|---|---|---|---|---|---|---|---|
| | | Example 8 | Example 1 | Example 2 | Example 3 | Example 4 | Example 5 |
| Formulation | Olefin (co)polymer (1)*⁷ | 100 | 100 | 100 | 100 | 100 | 100 |
| (parts by | Organic peroxide*⁸ | 0.35 | 0.35 | 0.35 | 0.35 | 0.35 | 0.35 |
| weight) | Crosslinking agent*⁹ | 0.5 | 0.5 | 0.5 | 0.5 | 0.5 | 0.5 |
| | Silane coupling agent*¹⁰ | 0.3 | 0.3 | 0.3 | 0.3 | 0.3 | 0.3 |
| | Wavelength conversion material | H | I | J | K | L | M |
| | (resin particle) | | | | | | |
| | Resin-particle content | 0.3 | 0.3 | 0.3 | 0.3 | 0.3 | 0.3 |
| | (as organic rare earth complex) | 0.0003 | 0.0003 | 0.0003 | 0.0003 | 0.0003 | 0.0003 |
| Evaluation | Light beam transmittance (%) | 90.9 | 90.8 | 90.8 | 90.9 | 91.0 | 90.9 |
| results | Hygrothermal deterioration-test | 50.6 | 15.5 | 10.6 | 5.8 | 30.5 | 15.5 |
| | evaluation result (residual ratio (%)) | | | | | | |

Note:
*⁷EVA: Content of vinyl acetate content: 26 weight % (Ultracene 634, manufactured by Tosoh Corporation)
*⁸t-Butylperoxy-2-ethylhexyl monocarbonate (Perbutyl E, manufactured by NOF corporation)
*⁹Triallyl isocyanurate (TAIC, manufactured by Nippon Kasei Chemical CO., Ltd.)
*¹⁰γ-Methacryloxypropyltrimethoxysilane (manufactured by Shin-Etsu Chemical Co., Ltd.)

As shown in the Tables, it was demonstrated in the hygrothermal deterioration test that the fluorescence intensity of the wavelength conversion material does not readily decrease. The wavelength conversion material is composed of resin (fine) particles comprising an acrylic resin, which contains an organic rare earth complex and which is a polymer obtained by a reaction of a composition comprising methyl methacrylate as a (meth)acrylate monomer and ethylene glycol dimethacrylate, or 1,9-nonanediol dimethacrylate as a cross-linking agent in predetermined amounts and comprising an azo polymerization initiator as a polymerization initiator. Accordingly, it was demonstrated that the wavelength conversion material of the present invention maintains the wavelength conversion effect for a long term, and that the solar cell sealing film of the present invention is capable of maintaining the effect of improving power generation efficiency for a long term.

The present invention is not limited by the embodiments and Examples mentioned above and can be variously modified within the gist of the invention.

### INDUSTRIAL APPLICABILITY

According to the present invention, it is possible to provide a solar cell module that is improved in power generation efficiency of a solar cell due to the use of wavelength conversion material and is capable of maintaining high power generation efficiency for a long term.

### REFERENCE SIGNS LIST

11 Front-side transparent protecting member
12 Backside protecting member
13A Front-side sealing film
13B Backside sealing film
14 Solar cells

1. A wavelength conversion material composed of resin particles comprising an acrylic resin and an organic rare earth complex contained in the acrylic resin, wherein the acrylic resin is a polymer which is a reaction product of an acrylic resin composition comprising a (meth)acrylate monomer, a crosslinking agent and an azo polymerization initiator, wherein
the crosslinking agent is a compound represented by the following formula (I): 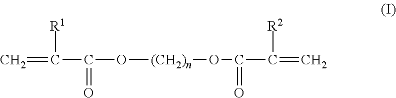
where R¹ and R² each independently represent a hydrogen atom or a methyl group and n represents an integer of 2 to 14, and
the content of the cross-linking agent is:
0.1 to 5 parts by mass based on 100 parts by mass of the (meth)acrylate monomer when n in formula (I) is 2; or
0.1 to 50 parts by mass based on 100 parts by mass of the (meth)acrylate monomer when n in formula (I) is 3 to 14.

2. The wavelength conversion material according to claim 1, wherein the cross-linking agent is a compound represented by formula (I) where R¹ and R² are methyl groups and n is 2.

3. The wavelength conversion material according to claim 1, wherein the cross-linking agent is a compound represented by formula (I) where R¹ and R² are methyl groups and n is 9.

4. The wavelength conversion material according to claim 1, wherein the (meth)acrylate monomer is methyl methacrylate.

5. The wavelength conversion material according to claim 1, wherein the organic rare earth complex is a europium complex represented by the following formula (II): 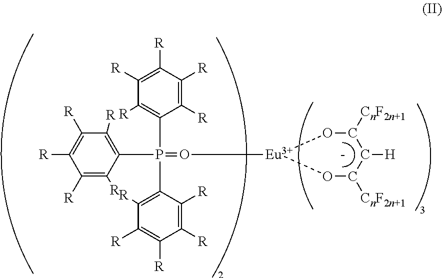
where R's each independently represent a hydrogen atom or a hydrocarbon group having 1 to 20 carbon atoms that may be optionally substituted; and n represents an integer of 1 to 4.

6. The wavelength conversion material according to claim 5, wherein the organic rare earth complex is a europium complex represented by formula (II) where R's all represent hydrogen atoms and n is 1.

7. A solar cell sealing film comprising a resin material comprising an olefin (co)polymer and the wavelength conversion material according to claim 1.

8. The solar cell sealing film according to claim 7, wherein the olefin (co)polymer is one or more polymers selected from the group consisting of metallocene catalyzed ethylene-α-olefin copolymers (m-LLDPE), low density polyethylenes (LDPE), linear low density polyethylenes (LLDPE), polypropylenes, poly butenes and etylene-polar monomer copolymers.

9. A solar cell module formed by sealing a solar cell with the solar cell sealing film according to claim 8.
